(19) United States
(12) Patent Application Publication
(10) Pub. No.: US 2026/0096420 A1
(43) Pub. Date: Apr. 2, 2026

(54) INTERCONNECT STRUCTURE HAVING METAL FEATURES WITH DIFFERENT VOLUME AND MATERIALS, AND METHOD FOR MANUFACTURING THE SAME

(71) Applicant: TAIWAN SEMICONDUCTOR MANUFACTURING COMPANY, LTD., Hsinchu (TW)

(72) Inventors: Cheng-Chin Lee, Hsinchu (TW); Chuan-Pu Chou, Hsinchu (TW); Ting-Ya Lo, Hsinchu (TW)

(73) Assignee: TAIWAN SEMICONDUCTOR MANUFACTURING COMPANY, LTD., Hsinchu (TW)

(21) Appl. No.: 18/904,707

(22) Filed: Oct. 2, 2024

(51) Int. Cl. H01L 23/528; H01L 21/768; H01L 23/532

(52) U.S. Cl. CPC H10W 20/435; H10W 20/056; H10W 20/067; H10W 20/4407; H10W 20/4424; H10W 20/4435; H10W 20/4446

(57) ABSTRACT

A method for manufacturing an interconnect structure includes: forming a base structure; forming a first metal feature on the base structure, the first metal feature having a first volume and including a first metallic material; forming a first dielectric layer surrounding the first metal feature and over the base structure; and forming a second metal feature in the first dielectric layer, the second metal feature being spaced apart from the first metal feature, having a second volume greater than the first volume, and including a second metallic material different from the first metallic material.

### BACKGROUND

Interconnect structure of a chip accounts for more than half of the capacitance of the chip, which means that the interconnect structure accounts for more than half of the dynamic power dissipation of the chip. Since such phenomenon causes significantly high RC delay, novel interconnect structure is required to minimize the RC delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2 to 13 are schematic views illustrating intermediate stages of the method for manufacturing the interconnect structure as depicted in FIG. 1 in accordance with some embodiments.

FIG. 14 is a flow diagram illustrating a method for manufacturing an interconnect structure with air gaps in accordance with some embodiments.

FIGS. 15 to 25 are schematic views illustrating intermediate stages of the method for manufacturing the interconnect structure as depicted in FIG. 14 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to an interconnect structure having, within a metal level, metal features that have different volumes and widths and that are made of different materials. For instance, a lower metal level of the interconnect structure includes a first metal feature and a second metal feature. The first metal feature is made of a first metallic material and has a first width with a first volume. The second metal feature is made of a second metallic material and has a second width with a second volume. In accordance with some embodiments of the present disclosure, the second width is at least three times greater than the first width, resulting in the second volume being greater than the first volume, and in such case, the second metallic material is different from the first metallic material. Specifically, the first and second metallic materials, when having different volumes, exhibit different electrical resistivities. When each of the first metallic material and the second metallic material has the first volume, an electrical resistivity of the first metallic material is smaller than an electrical resistivity of the second metallic material. When each of the first metallic material and the second metallic material has the second volume, an electrical resistivity of the second metallic material is smaller than an electrical resistivity of the first metallic material. As such, both the first and second metal features having different widths (and volumes) may have a relatively low electrical resistivity, so as to reduce resistance, thereby reducing RC delay of the interconnect structure.

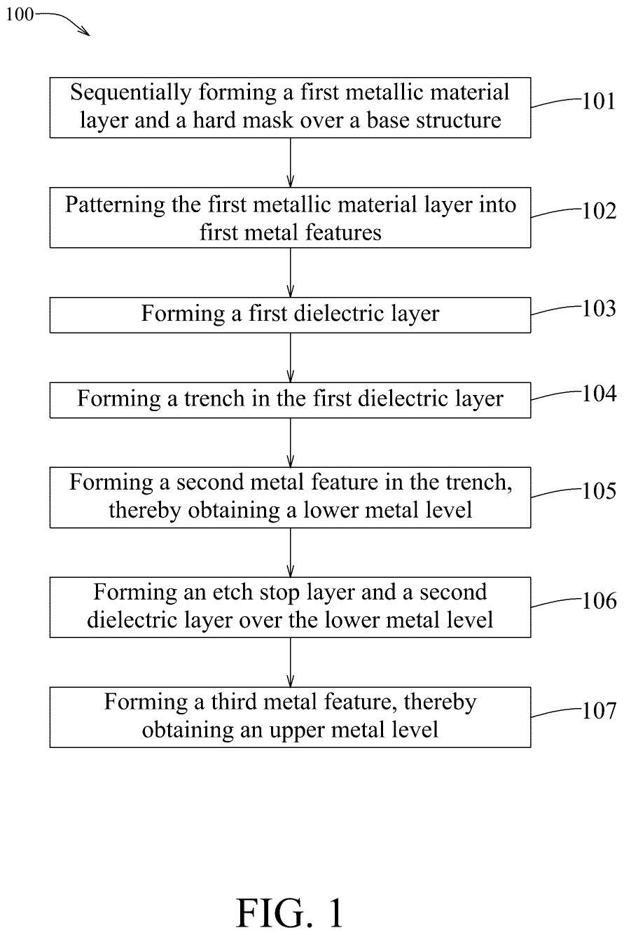

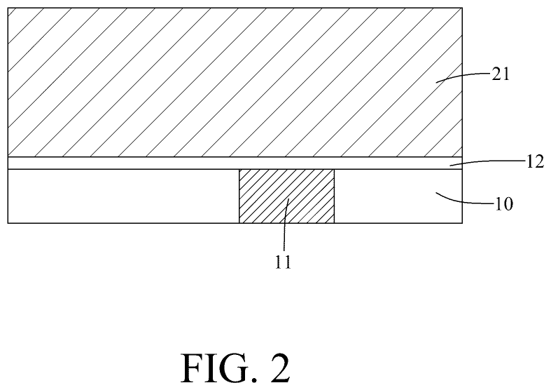

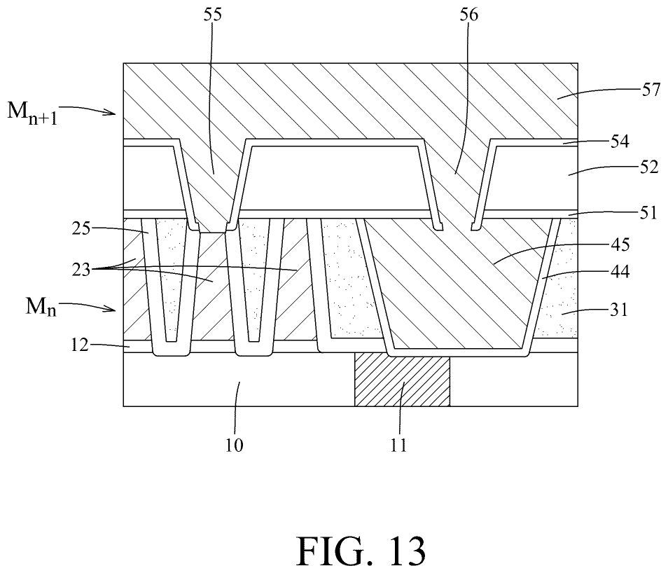

FIG. 1 is a flow diagram illustrating a method 100 for manufacturing the interconnect structure (for example, the structure shown in FIG. 13) in accordance with some embodiments. FIGS. 2 to 13 illustrate schematic views of intermediate stages of the method 100 in accordance with some embodiments. Some repeating structures are omitted in FIGS. 2 to 13 for the sake of brevity. Additional steps can be provided before, after or during the method 100, and some of the steps described herein may be replaced by other steps or be eliminated.

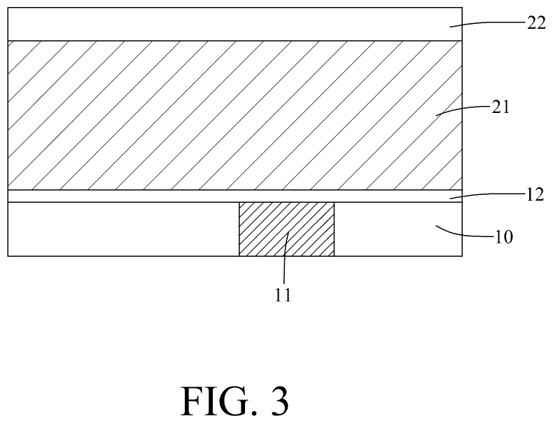

Referring to FIG. 1 and the examples illustrated in FIGS. 2 and 3, the method 100 begins at step 101, where a first metallic material layer 21 and a hard mask 22 are sequentially formed over a base structure 10.

In some embodiments, step 101 includes a first sub-step of forming an etch stop layer 12 and the first metallic material layer 21 over the base structure 10.

The base structure may include a substrate (not shown), and a front-end-of-line (FEOL) portion (not shown) formed on the substrate. The FEOL portion may include any suitable devices, such as planar transistors, fin-type field-effect transistors (FinFET), nanosheet semiconductor devices (e.g. gate-all-around field-effect transistors (GAAFET), forksheet field-effect transistors, complementary field-effect transistors (CFET), or the like), capacitors, resistors, or the likes, or combinations thereof. In some embodiments, the base structure 10 includes a conductive feature 11 formed therein. The conductive feature 11 may be a contact via connected to the device of the FEOL portion. Other suitable devices and/or elements for the base structure 10 are within the contemplated scope of the present disclosure.

The etch stop layer 12 may include a dielectric material, such as a metal nitride, a metal oxide, a metal carbide, silicon nitride, silicon oxide, silicon carbide, silicon oxynitride, or combinations thereof. Other suitable materials for the etch stop layer 12 are within the contemplated scope of the present disclosure.

The first metallic material layer 21 is to be formed into first metal features 23 as shown in FIG. 13. The first metallic material layer 21 (the first metal features 23) includes, or is made of a first metallic material that exhibits a relatively low electrical resistivity when being applied to form the first metal features 23 with a relatively small volume. In some embodiments, the first metallic material includes or is made of ruthenium (Ru), rhodium (Rh), tungsten (W), molybdenum (Mo), or combinations thereof, but are not limited thereto. The first metallic material layer 21 may be formed using any suitable deposition process, such as physical vapor deposition (PVD), atomic layer deposition (ALD), plasma enhanced chemical vapor deposition (PECVD), but are not limited thereto. Other suitable materials and/or processes for forming the first metallic material layer 21 (the first metal features 23) are within the contemplated scope of the present disclosure.

In some embodiments, step 101 further includes a second sub-step of forming a hard mask 22 over the first metallic material layer 21. The hard mask 22 may have a thickness ranging from about 300 Å to about 500 Å. The hard mask 22 may include or be made of titanium nitride (TiN), tungsten nitride (WN), tungsten carbide (WC), silicon nitride (SiNx), a metal nitride, a metal carbide, or the likes, or combinations thereof. The hard mask 22 may be formed using any suitable deposition process, such as physical vapor deposition (PVD), plasma-enhanced atomic layer deposition (PEALD), thermal atomic layer deposition (ALD), plasma enhanced chemical vapor deposition (PECVD), but are not limited thereto. Other suitable materials and/or thickness range and/or processes for forming the hard mask 22 are within the contemplated scope of the present disclosure.

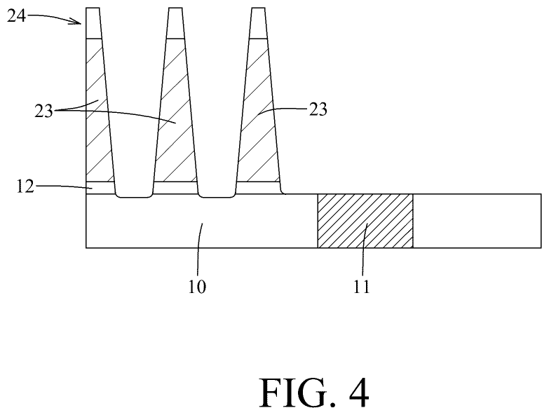

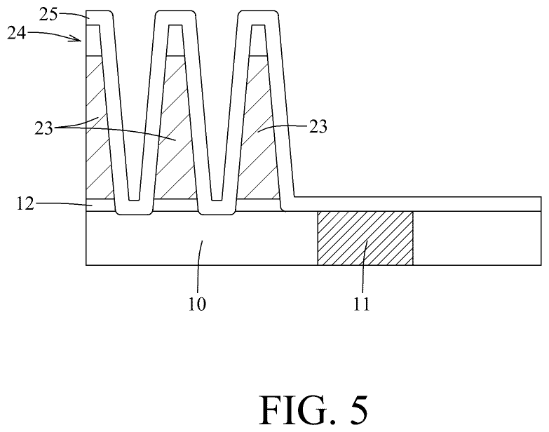

Referring to FIG. 1 and the examples illustrated in FIGS. 4 and 5, the method 100 proceeds to step 102, where the first metallic material layer 21 (see FIG. 3) is patterned into first metal features 23.

Step 102 may include: patterning the hard mask 22 (see FIG. 3) into a patterned hard mask 24 through a photolithography process and an etching process; and patterning the first metallic material layer 21 through the patterned hard mask 24 so as to obtain the first metal features 23. In some embodiments, the photolithography process may be an extreme ultraviolet (EUV) lithography. In some embodiments, the patterning process may be a reactive ion etching (RIE) process. Other suitable processes for forming the first metal features 23 are within the contemplated scope of the present disclosure. In addition, in some embodiments, the etch stop layer 12 is also patterned through the first metal features 23.

Referring to FIG. 5, in some embodiments, step 102 may further include a sub-step of conformally forming a liner 25 (may be known as a RIE liner) over the first metal features 23, the patterned hard mask 24 and the base structure 10. The liner 25 is configured to prevent the metallic material of the first metal features 23 to diffuse to other elements of the interconnect structure. The liner 25 may include silicon oxycarbide (SiOₓC_{y}), silicon carbide (SiC), silicon nitride (SiN), or combinations thereof. The liner 25 may be formed using an ALD process, or a PECVD process, but is not limited thereto. The liner 25 may have a thickness ranging from about 10 Å to about 40 Å, and a spaced-apart distance between any two adjacent ones of the first metal features 23 is reduced to a range of about 2 nm to about 8 nm. Other suitable materials and/or processes and/or thickness range for the liner 25 are within the contemplated scope of the present disclosure.

After steps 101 and 102, the first metal features 23 are obtained. The first metal features 23 are designed as metal lines with relatively small width (especially in comparison with a second metal feature 45 as shown in FIG. 13), and each has a first width and a first volume. As such, the first metal features 23 made of the aforementioned first metallic material, when being formed with a relatively small volume, e.g., the first volume, exhibit a relatively low electrical resistivity. It is noted that although the first metal features 23 are not electrically connected to the conductive feature 11 (see FIG. 4), the first metal features 23 are electrically and respectively connected to other conductive features which are respectively formed in portions of the base structure 10 other than the conductive feature 11 in the cross-section view of the structure shown in FIG. 4.

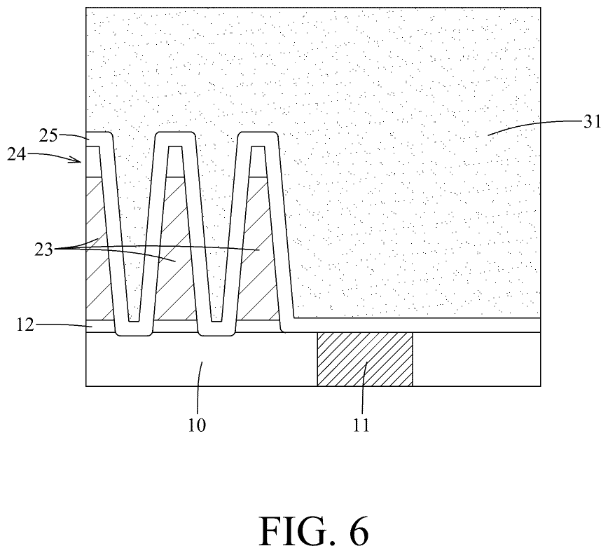

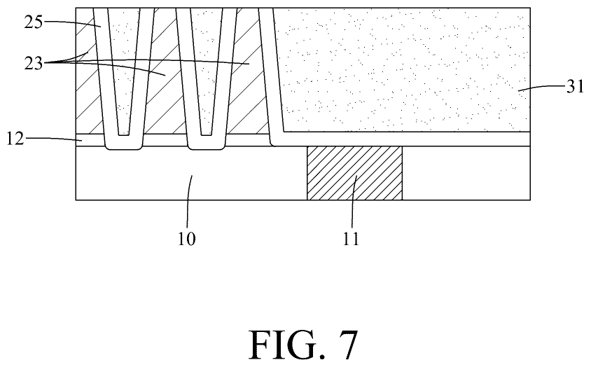

Referring to FIG. 1 and the examples illustrated in FIGS. 6 and 7, the method 100 proceeds to step 103, where a first dielectric layer 31 is formed surrounding the first metal features 23 and over the base structure 10.

Step 103 may include a first sub-step of depositing the first dielectric layer 31 to a level that is higher than the patterned hard mask 24 and the liner 25 disposed thereon (see FIG. 6), and a second sub-step of performing a planarization process (see FIG. 7), e.g., chemical-mechanical planarization (CMP) process, but is not limited thereto. After the CMP process, the patterned hard mask 24 is completely removed. In addition, portions of the liner 25 disposed on the patterned hard mask 24, and an excess amount of the first dielectric layer 31 are also removed. As such, the first dielectric layer 31 is formed to surround sidewalls of the first metal features 23 and portions of the liner 25 disposed on the sidewalls of the first metal features 23, while top surfaces of the first metal features 23 are exposed from the first dielectric layer 31.

In some embodiments, the first dielectric layer 31 include a low dielectric (low-k) material, but is not limited thereto, such as silicon carbon nitride (SiCₓN_{y}), boron carbon nitride (BCₓN_{y}), silicon oxide (SiOₓ), silicon nitride (SiNₓ), silicon carbide (SiCₓ), silicon oxycarbide (SiOₓC_{y}), silicon oxynitride (SiOₓN_{y}), hydrogenated silicon oxycarbide (SiOₓC_{y}H_{z}), spin-on glass (SOG), amorphous fluorinated carbon, borophosphosilicate glass (BPSG), fluorinated silica glass (FSG), xerogel, aerogel, polyimide, parylene, bis-benzocyclobutenes, porous materials, or combinations thereof. The first dielectric layer 31 may be formed using plasma enhanced chemical vapor deposition (PECVD), plasma enhanced atomic layer deposition (PEALD), spin coating, or the likes. Other suitable materials and/or processes for forming the first dielectric layer 31 are within the contemplated scope of the present disclosure.

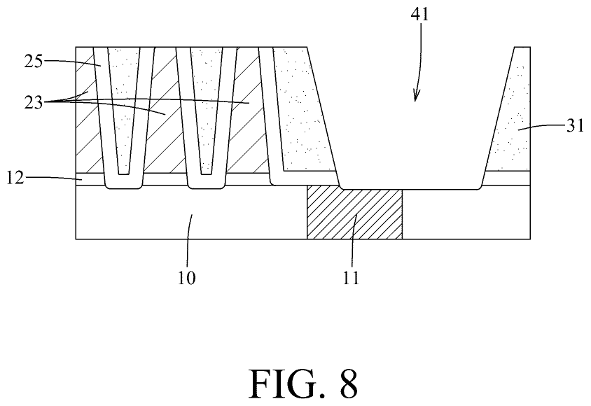

Referring to FIG. 1 and the example illustrated in FIG. 8, the method 100 proceeds to step 104, where a trench 41 is formed in the first dielectric layer 31.

The trench 41 may be located away from the first metal features 23. In this exemplary embodiments, as shown in FIG. 8, there is only one trench 41, which penetrates through the first dielectric layer 31 and the liner 25 so as to expose the conductive feature 11. In other embodiments, there may be more than one trench 41, and the conductive feature 11 shown in FIG. 8 is not necessarily exposed from the trench 41 but may expose the other conductive features (not shown) in other portions of the base structure 10. The trench 41 may be formed using any suitable process, such as a patterning process involving an etching process, but is not limited thereto. Other suitable processes for forming the trench 41 are within the contemplated scope of the present disclosure. The trench 41 is to accommodate a second metal feature 45 (see FIG. 13), which as has a relatively large width and volume. Thus, in some embodiments, in forming the trench 41, a 1-patterning-1-etching (1P1E) process is adopted without using a EUV process for reduced cost, but is not limited thereto. In some other embodiments, the EUV process may also be used.

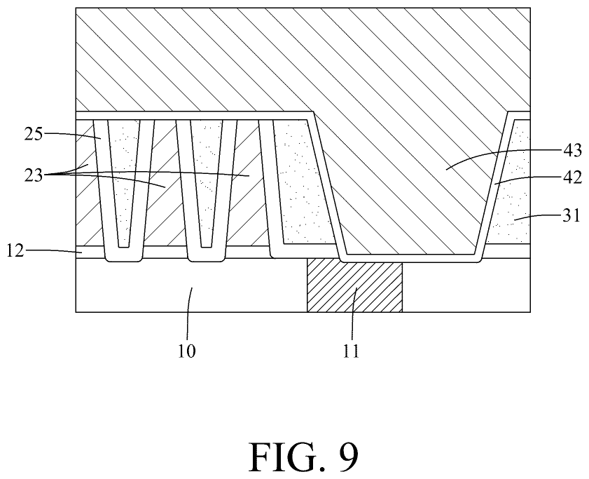

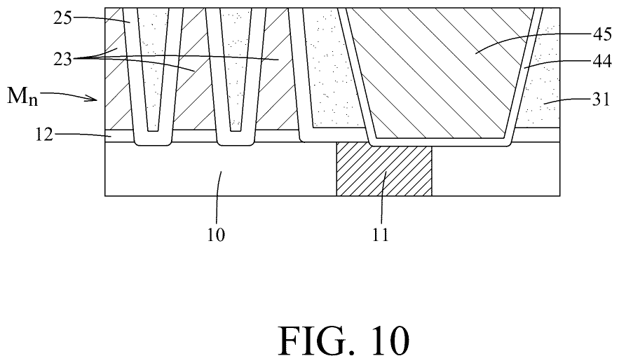

Referring to FIG. 1 and the examples illustrated in FIGS. 9 and 10, the method 100 proceeds to step 105, where a second metal feature 45 is formed in the trench 41 (see FIG. 8).

The step 105 may include sub-steps of: sequentially depositing a barrier material layer 42 and a second metallic material layer 43 in the trench 41 (see FIG. 8) and over first metal features 23 and the first dielectric feature 31 (see FIG. 9), followed by a planarization process (see FIG. 10), such as a CMP process, but is not limited thereto. The CMP process removes an excess amount of each of the barrier material layer 42 and the second metallic material layer 43 to obtain the barrier 44 and the second metal feature 45. In addition, the first metal features 23 and the first dielectric layer 31 (see FIG. 10) are exposed after the CMP process, and thus top surfaces of the first and second metal features 23, 45 are substantially flush with each other. Other suitable processes for forming the second metal feature 45 are within the contemplated scope of the present disclosure.

The second metallic material layer 43 is to be formed into the second metal feature 45, which is considered as a relatively large width metal line, especially in comparison with the first metal features 23. In some embodiments, the second metal feature 45 may have a width that is at least three times greater than the width of each of the first metal features 23. In some embodiments, when a plurality of the second metal features 45 are included and a pitch between two adjacent ones of the second metal features 45 is approximately greater than 60 nm, a pitch between two adjacent ones of the first metal features 23 may be not greater than 20 nm, but is not limited thereto. Other suitable ranges of pitch for the first metal features 23 and the second metal feature(s) 45 are within the contemplated scope of the present disclosure.

The second metallic material layer 43, or the second metal feature 45 includes, or is made of a second metallic material that exhibits a relatively low electrical resistivity when being applied to form the relatively large volume second metal feature 45. In some embodiments, the second metallic material includes or is a single-element metal, such as copper (Cu), cobalt (Co), nickel (Ni), iridium (Ir), platinum (Pt), iron (Fe), aluminum (Al), or the likes, or combinations thereof; or a binary metal, such as iron/cobalt alloy (FeCo), iron/aluminum (FeAl) alloy, or the likes, or combinations thereof, but are not limited thereto. The second metallic material layer 43 may be formed using any suitable deposition process, such as physical vapor deposition (PVD), atomic layer deposition (ALD), plasma enhanced chemical vapor deposition (PECVD), but are not limited thereto. Other suitable materials for forming the second metallic material layer 43 (the second metal feature 45) are within the contemplated scope of the present disclosure.

After completing step 105, a lower metal level (Mₙ) is obtained. The lower metal level (Mₙ) includes the first dielectric layer 31, the first metal features 23 and the second metal feature 45 that is formed in the first dielectric layer 31. It is noted that the first metal features 23 have the relatively small first width and first volume, whereas the second metal feature 45 has the relatively large second width and second volume. Given that different metallic materials, when being formed with different volumes, may exhibit different electrical resistivities, the first and second metal features 23, 45 of the present disclosure formed with different volumes (widths) are therefore designed to utilize different metallic materials so that both the first metal features 23 with smaller-volume (width) and the second metal feature 45 with larger-volume (width) could achieve a relatively small electrical resistivity. Specifically, when each of the first metallic material and the second metallic material has the first volume (i.e., the first metal features 23 with the comparatively smaller volume as shown in FIG. 8), an electrical resistivity of the first metallic material is smaller than an electrical resistivity of the second metallic material. Vice versa, when each of the first metallic material and the second metallic material has the second volume (i.e., the second metal feature 45 with the comparatively larger volume as shown in FIG. 8), an electrical resistivity of the second metallic material is smaller than an electrical resistivity of the first metallic material. Hence, the first metal features 23 having the relatively small first volume are made of the first metallic material, while the second metal feature 45 having the relatively large second volume is made of the second metallic material.

In consideration of the different properties of the first and second metallic materials, and challenges in forming the different widths (i.e., the smaller first width and the larger second width), the first and second metal features 23, 45 are formed using different approaches. For instance, the first metallic material generally lacks feasibility of gap-filling, and thus the first metal features 23 are formed by first depositing the first metallic material layer 21, followed by patterning the first metallic material layer 21 (steps 101 and 102 described with reference to FIGS. 2 to 5) using RIE process. In the patterning process, EUV process is adopted so as to form the first metal features 23 with the comparatively smaller first width. In contrast, given the second width being much larger than the first width, it is much easier to form the trench 41, which is used to accommodate the second metal feature 45 (in comparison with the case of forming narrow trenches to accommodate the first metal features 23), by simply using a 1-patterning-1-etching (1P1E) process (step 104 described with reference to FIG. 8). In addition, the second metallic material generally has good feasibility of gap-filling, and is ideally used to form the second metal feature 45 by deposition of the second metallic material in the trench 41, followed by the CMP process (step 105 described with reference to FIGS. 9 and 10). Steps 104 and 105 may be cooperatively known as a damascene process. That is, the second metal feature 45 is formed using a damascene process. It should be noted that forming the trench 41 is prone to overetching of the first dielectric layer 31, and may result in undesirable increment in capacitance when the trench 41 in the overetched first dielectric layer 31 is undesirably filled additionally with the second metallic material. Such increment in capacitance is even more significant when the damascene process is used to form the first metal features 23 having the relatively small first width. Therefore, the damascene process which involves etching of the first dielectric layer 31 is more suitable to be applied in forming the second metal feature 45 having the relatively large second width.

In the exemplarily embodiment shown in FIG. 8, the second metal feature 45 is electrically connected to the conductive feature 11 of the base structure 10. In other embodiments, the first metal features 23 (or only one of which) are electrically connected to the conductive feature 11.

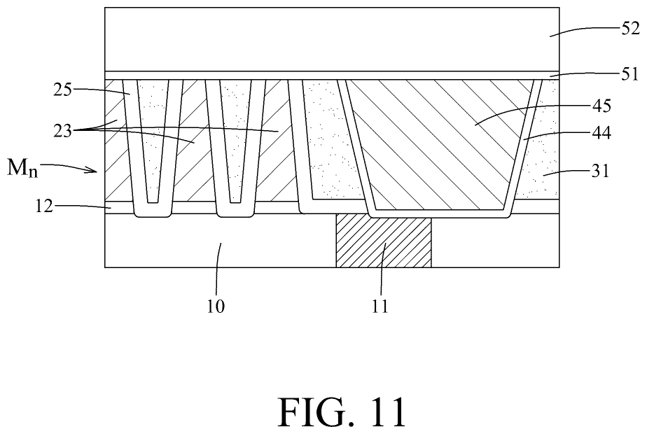

Referring to FIG. 1 and the example illustrated in FIG. 11, the method 100 proceeds to step 106, where an etch stop layer 51 and a second dielectric layer 52 are formed over the lower metal level (Mₙ).

The materials and formation of each of the etch stop layer 51 and the second dielectric layer 52 are similar to those of the etch stop layer 12 and the first dielectric layer 31 described with reference to FIG. 2, and thus details thereof are omitted for the sake of brevity.

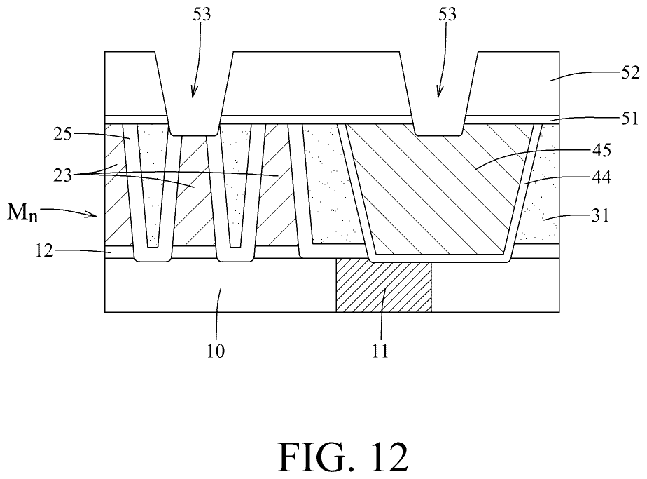

Referring to FIG. 1 and the examples illustrated in FIGS. 12 and 13, the method 100 proceeds to step 107, where a third metal feature 57 is formed over the lower metal level (Mₙ).

In some embodiments, step 107 includes a first sub-step of forming two openings 53 penetrating through the second dielectric layer 52 and the etch stop layer 51, so as to expose the second metal feature 45 and one of the first metal features 23, respectively (see FIG. 12). In the exemplary embodiments, the middle one of the first metal features 23 is exposed, but is not limited thereto. The step 107 further includes a second sub-step of sequentially forming a barrier layer 54 and a third metallic material layer over the second dielectric layer 52 and filling the openings 53, so as to obtain the third metal feature 57 (see FIG. 13). In some embodiments, the barrier layer 54 is selectively deposited on merely the second dielectric layer 52, but not on the first and second metal features 23, 45. Portions of the third metallic material layer that fill the openings 53 serve as vias 55, 56, respectively. The via 55 interconnects a middle one of the first metal feature 23 and the third metal feature 57, while the via 56 which interconnects the second metal feature 45 and the third metal feature 57. A remaining portion of the third metallic material layer that is disposed on the second dielectric layer 52 and the vias 55, 56 serves as the third metal feature 57.

The third metal feature 57 contributes to an upper metal level (Mₙ₊₁) which is disposed on the lower metal level (Mₙ) opposite to the base structure 10. In comparison with the lower metal level (Mₙ), metal features at the upper metal level (Mₙ₊₁) generally is made of larger width and volume. Specifically, in some embodiments, the third metal feature 57 has a third width (or third volume) that is not smaller than the second width (or the second volume) of the second metal feature 45. In order to achieve a relatively small electrical resistivity, the third metallic material (for making the third metal feature 57) is different from the first metallic material, and may be similar to or same as the second metallic material (for making the second metal feature 45).

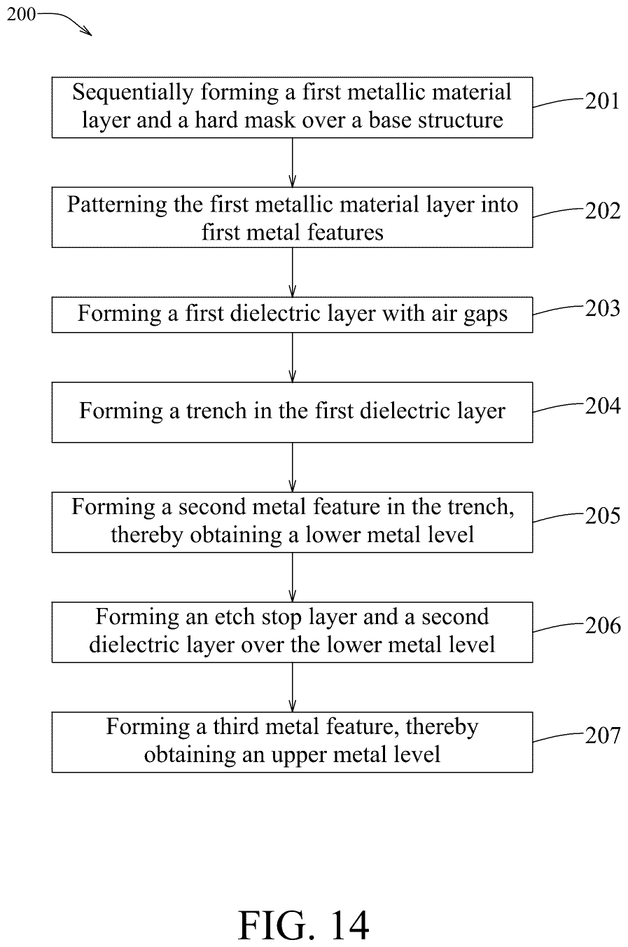

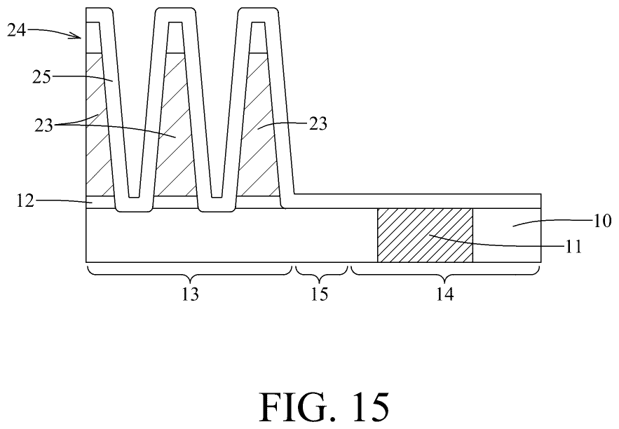

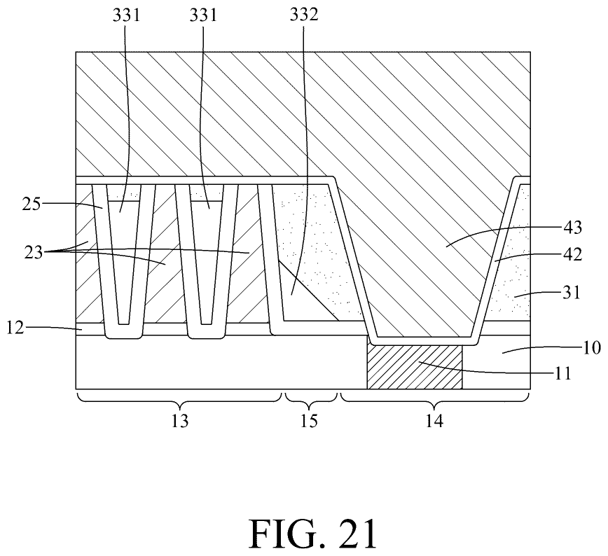

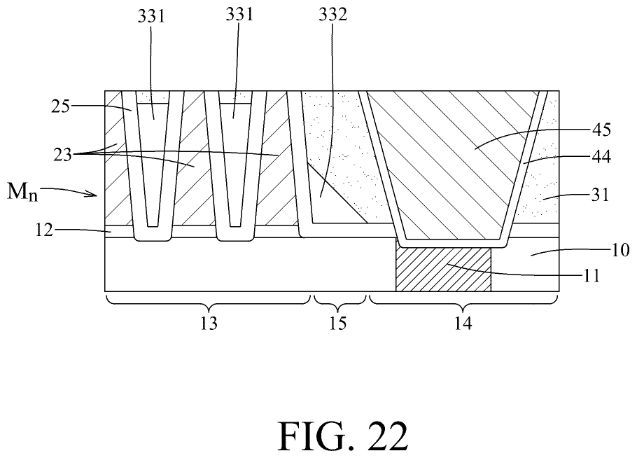

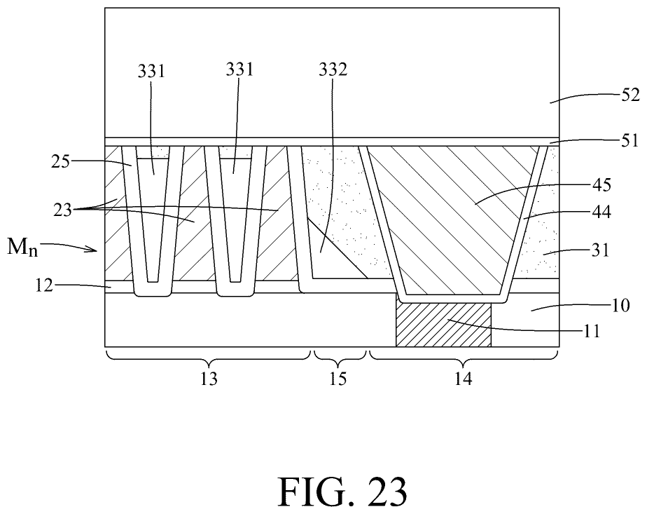

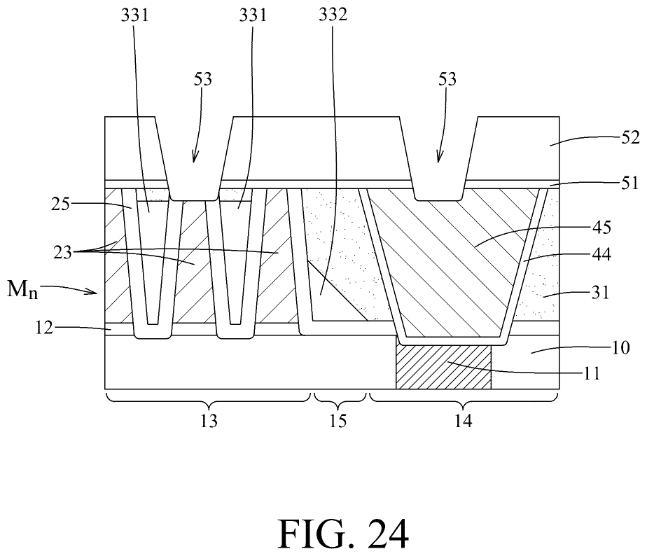

In some embodiments, in order to further reduce capacitance of the interconnect structure of the present disclosure, air gaps may be introduced in the dielectric layer, e.g., the first dielectric layer 31, but is not limited thereto. FIG. 14 is a flow diagram illustrating a method 200 for manufacturing an interconnect structure with air gaps in accordance with some embodiments. FIGS. 15 to 25 illustrate schematic views of intermediate stages of the method 200 for manufacturing the interconnect structure in accordance with some embodiments. Some repeating structures are omitted in FIGS. 15 to 25 for the sake of brevity. Additional steps can be provided before, after or during the method 200, and some of the steps described herein may be replaced by other steps or be eliminated.

Steps 201 and 202 are similar to steps 101 and 102, respectively, and therefore the details thereof are omitted for the sake of brevity. FIG. 15 illustrates a structure after completion of step 202, where the first metal features 23 and the liner 25 are formed. Please note that the structure of FIG. 15 is similar to that of FIG. 5, except that the position of the conductive feature 11 of the base structure 10 is a bit different merely to facilitate illustration of the subsequent steps. Please note that position of the conductive feature 11 is not limited thereto, and may be determined based on practical needs and product design.

Referring to FIG. 15, the first metal features 23 are formed across merely a first region 13 of the base structure 10, such that the first metal features 23 are not formed on a second region 14 and a third region 15 of the base structure 10. The first, second and third regions 13, 14, 15 are displaced from each other, and the third region 15 is located between the first and second regions 13, 14. The first metal features 23 are spaced apart from each other at the first region 13 by an in-between space with a predetermined distance, which is known as the spaced-apart distance as aforementioned with reference to FIG. 5. As shown in FIG. 15, left side of the third region 15 is adjacent to the rightmost one of the first metal features 23 at the first region 13, while right side of the third region 15 is a void formed at the second region 14.

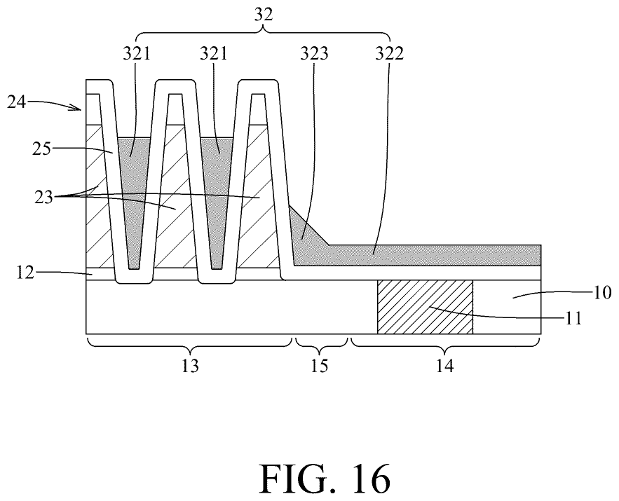

Referring to FIG. 14 and the example illustrated in FIGS. 16 to 19, the method 200 proceeds to step 203, where a first dielectric layer 31 with first air gaps 331 and a second air gap 332 is formed.

In some embodiments, step 203 includes four sub-steps. In the first sub-step of step 203, a sacrificial layer 32 is formed over the first metal features 23, the liner 25 and the base structure 10. In some embodiment, a sacrificial material layer (not shown) is formed over the structure shown in FIG. 15. The sacrificial material layer may have an upper surface located at a level that is higher than or lower than the top surfaces of the first metal features 23. The sacrificial material layer may be a polymer film including polyurea, polylactic acid, polycaprolactone, poly(methyl methacrylate), poly(ethylene oxide), or the likes, or combinations thereof. The sacrificial material layer may be formed using flowable chemical vapor deposition (FCVD), spin-coating, molecular layer deposition (MLD), or atomic layer deposition (ALD), or other suitable processes. In some embodiments, after forming the sacrificial material layer, an excess amount of the sacrificial material layer may be removed or etched back, so as to obtain the sacrificial layer 32 using, for instance, a UV exposure process, a plasma etching process, an annealing process, but are not limited thereto. As such, after the first sub-step of step 203, upper surface of the sacrificial layer 32 is located below the top surfaces of the first metal features 23 (which may be controlled by duration of the etching back process). Other suitable materials and/or processes for forming the sacrificial layer 32 are within the contemplated scope of the present disclosure. In forming the sacrificial layer 32, loading effect is observed and permits specific configuration of the sacrificial layer 32. Specifically, the sacrificial layer 32 has first portions 321, a second portion 322, and a third portion 323. The first portions 321 are located among the first metal features 23 at the first region 13. Specifically, each of the first portions 321 is disposed between two adjacent ones of the first metal features 23. Please note that after the first sub-step of step 203, upper surfaces of the first portions 321 are located below the top surfaces of the first metal features 23. The second portion 322 and the third portion 323 are located at the second region 14 and the third region 15, respectively. Since the first metal features 23 are spaced apart from each other by a relatively smaller distance, a height of the each of the second portion 322 and the third portion 323 is smaller than a height of the first portions 321. Because of the viscous property of the polymer, the third portion 323 has a slanted upper surface which is inclined relative to an upper surface of each of the first portions 321.

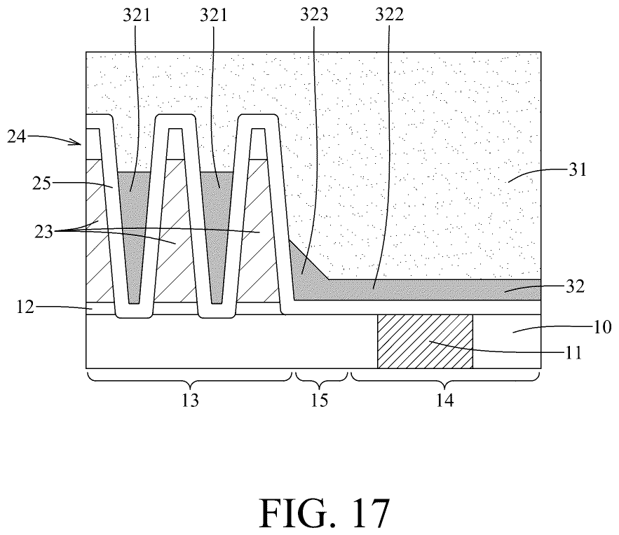

Referring to FIG. 17, in the second sub-step of step 203, a first dielectric layer 31 is deposited over the liner 25 and covering the sacrificial layer 32. The second sub-step of step 203 illustrated in FIG. 17 is similar to the first sub-step of step 103 shown in FIG. 6, except that the low dielectric material of the first dielectric layer 31 used in FIG. 17 is a porous material, so as to facilitate removal of the sacrificial layer 32 performed in the third sub-step of step 203. Other details of depositing the first dielectric layer 31 have been described with reference to FIG. 6, and details thereof are omitted for the sake of brevity.

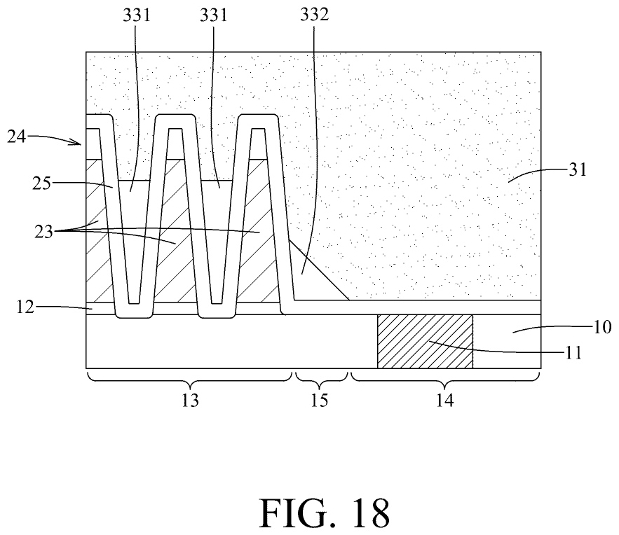

Referring to FIG. 18, in the third sub-step of step 203, the sacrificial layer 32 is removed. In some embodiments, the sacrificial layer 32 may be burnt out and converted from solid phase to gas phase by any suitable process, such as annealing, a plasma process, or a UV exposure process, but is not limited thereto. Other suitable processes for removing the sacrificial layer 32 are within the contemplated scope of the present disclosure. The gas phase sacrificial layer 32 may then pass through the porous first dielectric layer 31. At the first region 13, after removing the first portions 321 of the sacrificial layer 32, first portions of the first dielectric layer 31 disposed thereon are supported by the first metal features 23, thus leaving the first air gaps 331 formed between the first dielectric layer 31 and the liner 25 at the first region 13. That is, each of the first air gaps 331 is located between two adjacent ones of the first metal features 23. Each of the first air gaps 331 is bordered by the first dielectric layer 31 at the first region 13, and two adjacent ones of the first metal features 23, and the liner 25 disposed thereon. A lower surface of the first dielectric layer 31 at the first region 13 is at a level lower than the top surfaces of the first metal features 23. At the second region 14, after removing the second portion 322 of the sacrificial layer 32, a second portion of the first dielectric layer 31 disposed thereon lacks support and thus lowers down toward the base structure 10 to be in contact with the liner 25 at the second region 14. At the third region 15, after removing the third portion 323 of the sacrificial layer 32, a third portion of the first dielectric layer 31 disposed thereon is at least supported, at the left side, by the liner 25 and the rightmost one of the first metal features 23, while the right side lacks support and thus lowers down toward the base structure 10 to be in contact with the liner 25 at the third region 15. As such, the first dielectric layer 31 at the third region 15 has a slanted lower surface which is inclined relative to the first dielectric layer 31 at the first region 13, thereby forming a second air gap 332 which has a configuration different from that of the first air gaps 331. The second air gap 332 is bordered by the rightmost first metal feature 23, the base structure 10 and the surface region of the first dielectric layer 31 and the third region 15.

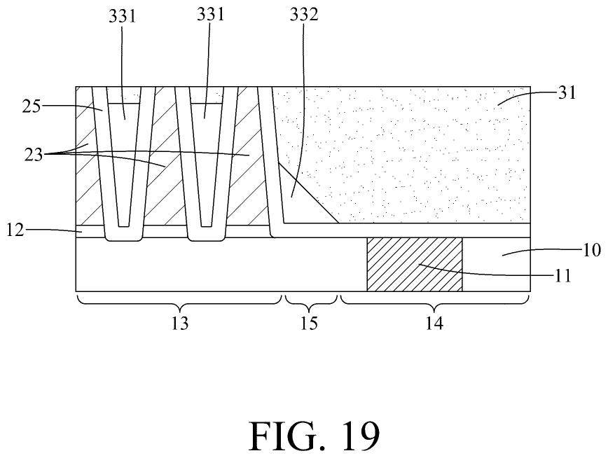

The fourth sub-step of step 203 illustrated in FIG. 19 is similar to the second sub-step of step 103 shown in FIG. 7, and thus the details thereof are omitted for the sake of brevity.

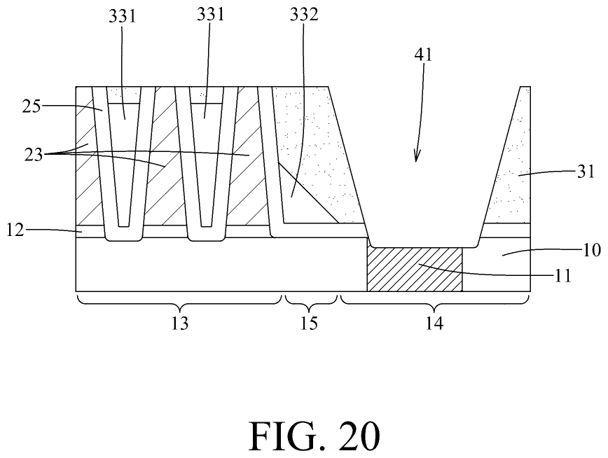

After completing step 203, the first and second air gaps 331, 332, and the first dielectric layer 31 are obtained. Steps 204 to 207, which are respectively illustrated by FIGS. 20 to 25, are similar to steps 104 to 107 respectively described with reference to FIGS. 8 to 13, and details thereof are omitted for the sake of brevity.

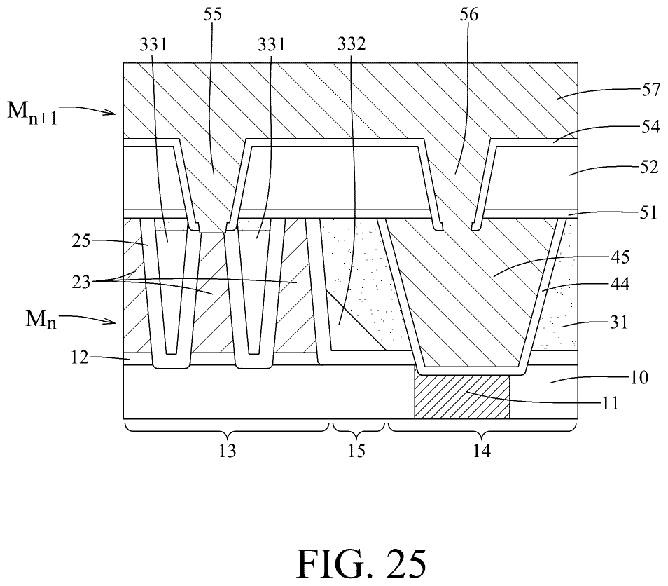

The interconnect structure shown in FIG. 25 is similar to that of FIG. 13, except that in FIG. 25, the first and second air gaps 331, 332 are formed around the first metal features 23, and can significantly reduce capacitance of the interconnect structure. This is conducive to reduce RC delay of the interconnect structure.

The embodiments of the present disclosure have the following advantageous features. The type of metallic material adopted in the metal features of the present disclosure is determined based on width and/or volume of the metal features. For instance, each of the first metal features 23 of the lower metal level (Mₙ) is designed to have a relatively small width (volume), and thus are formed to include or made of the first metallic material which exhibits a relatively low electrical resistivity at small volume. In contrast, the second metal feature of the lower metal level (Mₙ), and the third metal feature of the upper metal level (Mₙ₊₁) are designed to have a relatively large width (volume), and thus are formed to include or made of the second metallic material, which exhibits a relatively low electrical resistivity at large volume. The sequential steps for forming the first and second metal features are performed in accordance to the properties of each of the first and second metallic materials (e.g., the feasibility of gap-filling, but is not limited thereto). In addition, the configuration of the first and second air gaps that are configured to reduce capacitance of the interconnect structure are also described, along with manufacturing method thereof.

In accordance with some embodiments of the present disclosure, a method for manufacturing an interconnect structure includes: forming a base structure; forming a first metal feature on the base structure, the first metal feature having a first volume and including a first metallic material; forming a first dielectric layer surrounding the first metal feature and over the base structure; and forming a second metal feature in the first dielectric layer, the second metal feature being spaced apart from the first metal feature, having a second volume greater than the first volume, and including a second metallic material different from the first metallic material.

In accordance with some embodiments of the present disclosure, a width of the second metal feature is at least three times greater than a width of the first metal feature.

In accordance with some embodiments of the present disclosure, when each of the first metallic material and the second metallic material has the first volume, an electrical resistivity of the first metallic material is smaller than an electrical resistivity of the second metallic material.

In accordance with some embodiments of the present disclosure, when each of the first metallic material and the second metallic material has the second volume, an electrical resistivity of the second metallic material is smaller than an electrical resistivity of the first metallic material.

In accordance with some embodiments of the present disclosure, the first metallic material includes ruthenium, rhodium, tungsten, molybdenum, or combinations thereof.

In accordance with some embodiments of the present disclosure, the second metallic material includes copper, cobalt, nickel, iridium, platinum, iron, aluminum, or combinations thereof.

In accordance with some embodiments of the present disclosure, the method further includes forming a third metal feature over the first metal feature and the second metal feature opposite to the base structure, the third metal feature having a third volume not smaller than the second volume, and being made of a third metallic material that is same as the second metallic material.

In accordance with some embodiments of the present disclosure, the method further includes forming an air gap in the first dielectric layer.

In accordance with some embodiments of the present disclosure, the first dielectric layer is formed after forming the first metal feature, and the second metal feature is formed after forming the first dielectric layer.

In accordance with some embodiments of the present disclosure, forming the first metal feature includes: sequentially forming a first metallic material layer and a hard mask over the base structure; patterning the hard mask to form a patterned hard mask; and patterning the first metallic material layer through the patterned hard mask so as to obtain the first metal feature.

In accordance with some embodiments of the present disclosure, forming the second metal feature includes forming a trench in the first dielectric layer, and forming the second metal feature in the trench.

In accordance with some embodiments of the present disclosure, a method for manufacturing an interconnect structure includes: forming a base structure, the base structure having a first region and a second region that are displaced from each other; forming a first metallic material layer on the base structure; patterning the first metallic material layer so as to form first metal features at the first region and to expose the second region of the base structure, the first metal features being spaced apart from each other and including a first metallic material, each of the first metal features having a first width; forming a first dielectric layer surrounding the first metal features and over the base structure; patterning the first dielectric layer to form a trench in the first dielectric layer above the second region; and forming a second metal feature in the trench, the second metal feature having a second width greater than the first width, and including a second metallic material different from the first metallic material.

In accordance with some embodiments of the present disclosure, the second width is at least three times greater than the first width.

In accordance with some embodiments of the present disclosure, the first metallic material includes ruthenium, rhodium, tungsten, molybdenum, or combinations thereof.

In accordance with some embodiments of the present disclosure, the second metallic material includes copper, cobalt, nickel, iridium, platinum, iron, aluminum, or combinations thereof.

In accordance with some embodiments of the present disclosure, the method further includes: before forming the first dielectric layer, forming a sacrificial layer over the first metal features and the base structure, the sacrificial layer having first portions among the first metal features at the first region, and a second portion at the second region, a height of the second portion being smaller than a height of the first portions, wherein after forming the first dielectric layer, the sacrificial layer is covered by the first dielectric layer; and before forming the second metal feature, removing the sacrificial layer so that the first portions are respectively formed into first air gaps among the first metal features, and so that the second portion is removed to allow the first dielectric layer at the second region to be lowered down toward the base structure.

In accordance with some embodiments of the present disclosure, the sacrificial layer further has a third portion between the second portion and one of the first portions, the third portion having a slanted upper surface which is inclined relative to an upper surface of the one of the first portions so that after removing the sacrificial layer, the third portion is formed into a second air gap having a configuration different from a configuration of each of the first air gaps.

In accordance with some embodiments of the present disclosure, the base structure further has a third region between the first region and the second region, a lower surface of the first dielectric layer has an inclined surface region confronting the third region, and the second air gap is bordered by the inclined surface region and the third region.

In accordance with some embodiments of the present disclosure, an interconnect structure includes: a base structure including a conductive feature, and a lower metal level formed over the base structure. The lower metal level includes: a dielectric layer; and a first metal feature and a second metal feature that are formed in the dielectric layer. The first metal feature includes a first metallic material and has a first width. The second metal feature is spaced apart from the first metal feature, and includes a second metallic material different from the first metallic material. The second metal feature has a second width larger than the first width. One of the first metal feature and the second metal feature is electrically connected to the conductive feature.

In accordance with some embodiments of the present disclosure, the interconnect structure further includes an upper metal level formed over the lower metal level. The upper metal level includes a third metal feature that has a third metallic material different from the first metallic material.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a base structure;
forming a first metal feature on the base structure, the first metal feature having a first volume and including a first metallic material;
forming a first dielectric layer surrounding the first metal feature and over the base structure; and
forming a second metal feature in the first dielectric layer, the second metal feature being spaced apart from the first metal feature, having a second volume greater than the first volume, and including a second metallic material different from the first metallic material.

2. The method of claim 1, wherein a width of the second metal feature is at least three times greater than a width of the first metal feature.

3. The method of claim 1, wherein when each of the first metallic material and the second metallic material has the first volume, an electrical resistivity of the first metallic material is smaller than an electrical resistivity of the second metallic material.

4. The method of claim 1, wherein when each of the first metallic material and the second metallic material has the second volume, an electrical resistivity of the second metallic material is smaller than an electrical resistivity of the first metallic material.

5. The method of claim 1, wherein the first metallic material includes ruthenium, rhodium, tungsten, molybdenum, or combinations thereof.

6. The method of claim 1, wherein the second metallic material includes copper, cobalt, nickel, iridium, platinum, iron, aluminum, or combinations thereof.

7. The method of claim 1, further comprising forming a third metal feature over the first metal feature and the second metal feature opposite to the base structure, the third metal feature having a third volume not smaller than the second volume, and being made of a third metallic material that is same as the second metallic material.

8. The method of claim 1, further comprising forming an air gap in the first dielectric layer.

9. The method of claim 1, wherein the first dielectric layer is formed after forming the first metal feature, and the second metal feature is formed after forming the first dielectric layer.

10. The method of claim 9, wherein forming the first metal feature includes:
sequentially forming a first metallic material layer and a hard mask over the base structure;
patterning the hard mask to form a patterned hard mask; and
patterning the first metallic material layer through the patterned hard mask so as to obtain the first metal feature.

11. The method of claim 9, wherein forming the second metal feature includes
forming a trench in the first dielectric layer, and
forming the second metal feature in the trench.

12. A method for manufacturing an interconnect structure, comprising:
forming a base structure, the base structure having a first region and a second region that are displaced from each other;
forming a first metallic material layer on the base structure;
patterning the first metallic material layer so as to form first metal features at the first region and to expose the second region of the base structure, the first metal features being spaced apart from each other and including a first metallic material, each of the first metal features having a first width;
forming a first dielectric layer surrounding the first metal features and over the base structure;
patterning the first dielectric layer to form a trench in the first dielectric layer above the second region; and
forming a second metal feature in the trench, the second metal feature having a second width greater than the first width, and including a second metallic material different from the first metallic material.

13. The method of claim 12, wherein the second width is at least three times greater than the first width.

14. The method of claim 12, wherein the first metallic material includes ruthenium, rhodium, tungsten, molybdenum, or combinations thereof.

15. The method of claim 12, wherein the second metallic material includes copper, cobalt, nickel, iridium, platinum, iron, aluminum, or combinations thereof.

16. The method of claim 12, further comprising:
before forming the first dielectric layer, forming a sacrificial layer over the first metal features and the base structure, the sacrificial layer having first portions among the first metal features at the first region, and a second portion at the second region, a height of the second portion being smaller than a height of the first portions, wherein after forming the first dielectric layer, the sacrificial layer is covered by the first dielectric layer; and
before forming the second metal feature, removing the sacrificial layer so that the first portions are respectively formed into first air gaps among the first metal features, and so that the second portion is removed to allow the first dielectric layer at the second region to be lowered down toward the base structure.

17. The method of claim 16, wherein the sacrificial layer further has a third portion between the second portion and one of the first portions, the third portion having a slanted upper surface which is inclined relative to an upper surface of the one of the first portions so that after removing the sacrificial layer, the third portion is formed into a second air gap having a configuration different from a configuration of each of the first air gaps.

18. The method of claim 17, wherein
the base structure further has a third region between the first region and the second region,
a lower surface of the first dielectric layer has an inclined surface region confronting the third region, and
the second air gap is bordered by the inclined surface region and the third region.

19. An interconnect structure, comprising:
a base structure including a conductive feature; and
a lower metal level formed over the base structure, the lower metal level including:
a dielectric layer;
a first metal feature that is formed in the dielectric layer, that includes a first metallic material, and that has a first width; and
a second metal feature that is formed in the dielectric layer and spaced apart from the first metal feature, that includes a second metallic material different from the first metallic material, and that has a second width larger than the first width,
one of the first metal feature and the second metal feature being electrically connected to the conductive feature.

20. The interconnect structure of claim 19, further comprising an upper metal level formed over the lower metal level, the upper metal level including a third metal feature that has a third metallic material different from the first metallic material.
